(19) United States
(12) Patent Application Publication
(10) Pub. No.: US 2026/0273785 A1
(43) Pub. Date: Sep. 17, 2026

(54) NITRO-DIAMOND-LIKE-CARBON COATING ON SHAVING BLADE TIPS

(71) Applicant: Dollar Shave Club, Inc., Durham, NC (US)

(72) Inventors: Arie LAPID, Durham, NC (US); Jean RAMON, Durham, NC (US); Gideon HOOBERMAN, Durham, NC (US)

(21) Appl. No.: 19/564,042

(22) Filed: Mar. 11, 2026

Related U.S. Application Data
(60) Provisional application No. 63/770,623, filed on Mar. 12, 2025.

(51) Int. Cl. B26B 21/60; C23C 14/02; C23C 14/06; C23C 14/35

(52) U.S. Cl. CPC B26B 21/60; C23C 14/028; C23C 14/0611; C23C 14/35

(57) ABSTRACT

Disclosed here are systems and methods for the implementation of a new coating type, permitting to achieve better performance of razor blades. These systems and methods improve on carbon coatings to incorporate additional elements into its composition. Additionally, the coating process parameters achieve also a high degree of reduction of the tip radius.

### CROSS REFERENCE

This application is related to and claims priority from U.S. Provisional Application No. 63/770,623 filed on Mar. 12, 2025, the entirety of which is hereby incorporated by reference.

### TECHNICAL FIELD

This application relates to a method of manufacturing razor blade sharp edges. These include materials and coatings to provide an improved comfort for shaving experience and increased durability.

### BACKGROUND

Typically, a wet shaving razor blade is made of a thin stainless-steel blade, and then mechanically griding it into a sharpened tip. After the sharp cutting edge is ground, several steps of finishing coating processes may be applied to the edge, to achieve a lower friction coefficient and longer durability in use. The combination of geometrical shape and chemical composition of the cutting edge results in the finished product designed to impart the best shaving experience. The mechanically sharpened steel edge, being made of steel, has a limited functional behavior and lifespan. A harder, tougher and sharper tip would prove beneficial, as described in this disclosure.

### SUMMARY

Systems and methods here include method for manufacturing a shaving razor blade, the method including providing a heat-treated stainless-steel strip, grinding a sharpened cutting edge with a cutting edge tip on the stainless-steel strip, using a physical vapor deposition system for applying a bias voltage to the stainless-steel strip and depositing a Nitrogen-containing Diamond Like Carbon (NDLC) coating by directional ion beams of Argon, Nitrogen, and Carbon and thereby coating the blade cutting edge tip and also sharpening the blade cutting edge tip.

In some examples, alone or in combination, the sharpening of the blade tip to a radius of about 0.02 μm. In some examples, alone or in combination, the physical vapor deposition system bias voltage level is between 0 kV and 30 kV. In some examples, alone or in combination, further comprising, depositing a first Cr coating on the cutting edge using a physical vapor deposition system, before the NDLC coating. In some examples, alone or in combination, further comprising, depositing a second Cr coating on the NDLC layer using the physical vapor deposition system.

In some examples, alone or in combination, further comprising, applying an adherent polymer coating for reducing friction coefficient. In some examples, alone or in combination, the NDLC is deposited by a magnetron sputter coating source. In some examples, alone or in combination, the NDLC is deposited in an evacuated chamber in which a graphite target is used. In some examples, alone or in combination, the NDLC is deposited in an evacuated chamber in which a composite carbon target with any one or any combination of silicon (Si), zirconium (Zr), chromium (Cr), niobium (Nb), tungsten (W), boron (B), and/or titanium (Ti). In some examples, alone or in combination, the evacuated chamber atmosphere includes any combination of Argon, Nitrogen, Fluorine-containing, and/or Carbon-containing gas, at low pressure. In some examples, alone or in combination, the directional ion beams of Argon, Nitrogen, and Carbon beam of ions is at an angle of less than 25 degrees relative to the blade edge tip sides. In some examples, alone or in combination, the physical vapor deposition system includes a high energy source having an energy of at least 10 volts.

In some examples, alone or in combination, further comprising multiple stainless-steel strips combined into stacks and wherein Sputter Power for the powered physical vapor deposition system used for each blade stack is between 500 W and 5000 W. In some examples, alone or in combination, the physical vapor deposition system uses a power supply that is a pulsed DC with a Pulse Frequency of between 50 kHz and 30,000 kHz.

In some examples, alone or in combination, the physical vapor deposition system has a Reversed Pulse Time of between 0 μs-100 μs. In some examples, alone or in combination, the physical vapor deposition system includes Nitrogen gas concentration between 0 vol % and 70 vol %. In some examples, alone or in combination, bias voltage is between 0.5 kV-3 kV. In some examples, alone or in combination, a time to apply all the layers to the blades is between 25 seconds and 25,000 seconds. In some examples, alone or in combination, the NDLC coating results in a blade cutting edge having between 53% weight C and 93% weight C. In some examples, alone or in combination, the NDLC coating results in a blade edge having between 7% weight N and 47% weight N.

Systems and methods here may include a razor blade having a stainless-steel strip with a sharpened cutting edge, the stainless-steel strip cutting edge including a nitrogen-containing diamond-like carbon (NDLC) coating on the stainless-steel cutting edge and tip, from the physical vapor deposition system, wherein the NDLC coating is from directional voltage biased ion beams of Argon, Nitrogen, and Carbon in the physical vapor deposition system, wherein the NDLC coating results in a blade having between 53-93% weight C and 7-47% weight N. In some examples, alone or in combination, a first Cr coating from a physical vapor deposition system, before the NDLC coating. In some examples, alone or in combination, a second Cr coating on the cutting edge on top of the NDLC coating from the physical vapor deposition system. In some examples, alone or in combination, the tip is honed using a directional ion beam shaping with a bias between the stainless-steel strip and a carbon target and a cutting edge tip radius of about 0.02 μm after the NDLC coating using directional voltage biased ion beams. In some examples, alone or in combination, the voltage bias is between 0 kV and 30 kV. In some examples, alone or in combination, the physical vapor deposition system includes Nitrogen gas concentration between 0 vol % and 70 vol %.

### BRIEF DESCRIPTION OF THE DRAWINGS

For a better understanding of the embodiments described in this application, reference should be made to the Detailed Description below, in conjunction with the following drawings in which reference numerals refer to corresponding parts throughout the figures.

FIG. 1 is an example diagram of a blade cross section with coatings according to examples described herein;

FIGS. 2 and 3 are example images taken by scanning electron microscope of a blade edge with and without an NDLC coating according to examples described herein;

FIG. 4 is an example flow chart diagram of the coating methods according to examples described herein;

FIG. 5 is an example image taken by scanning electron microscope of a blade edge with an NDLC coating;

FIG. 6 is an example diagram showing plasma ion beam shaping of a blade cross section according to examples described herein; and

FIG. 7 is an example diagram showing a scanning electron microscope of a blade edge made using the systems and methods described herein.

### DETAILED DESCRIPTION

Reference will now be made in detail to embodiments, examples of which are illustrated in the accompanying drawings. In the following detailed description, numerous specific details are set forth to provide a sufficient understanding of the subject matter presented herein. It will be apparent to one of ordinary skill in the art that the subject matter may be practiced without these specific details. Moreover, the embodiments described herein are provided by way of example and should not be used to limit the scope of the disclosures to these particular embodiments.

### Coated Blade Overview

The razor blades found in most safety razor cartridges today are not just bare metal ground into a sharp edge but include various different coatings and treatments on the blades in order to help strengthen the blades, sharpen the blades, reduce friction for the blades when in use, and otherwise make for a more comfortable shaving experience. Systems and methods described here include new technologies to achieve better results in a proven way.

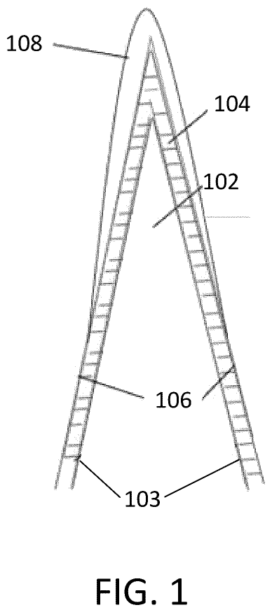

FIG. 1 shows a cross-section drawing detail of a multi-layered example of such a razor blade 102 as described herein. FIG. 1 shows various coatings applied to the metal substrate blade 102, which may be applied using the systems and methods described herein. One such example coating includes a nitrogen doped diamond like carbon layer (NDLC) capable of enhancing strength and durability of the cutting sharpened edge.

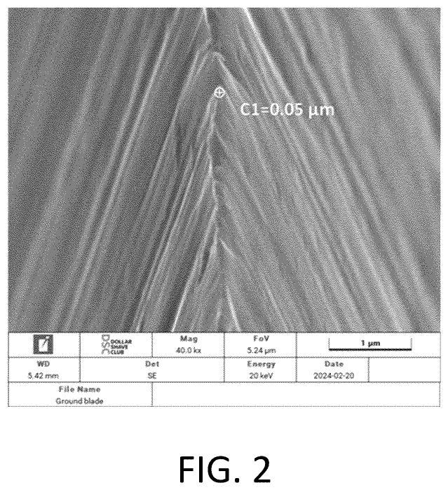

As shown in the FIG. 1 cross-section of a blade edge, the blade substrate 102 is shown at the core. In some examples, this substrate 102 is made of steel and sharpened into a point tip. It is this blade edge and tip that is used for shaving when in use. FIG. 2 shows a photo taken at microscopic level of a bare metal blade edge. The radius at the tip of this blade edge shown is measured at 0.05 μm+/−0.04 μm. A bare metal blade edge as shown is good, giving a satisfactory shaving experience, but the new method described in this invention imparts a much improved one.

Turning back to the example of FIG. 1 shows an optional layer 103 formed on top of the substrate 102. In some examples, this optional layer may be made of Cr or any number of materials including but not limited to Cr. Other optional materials, alone or in any combination include, silicon (Si), zirconium (Zr), chromium (Cr), niobium (Nb), tungsten (W), boron (B), and/or titanium (Ti). This layer on the substrate, if utilized, may serve as a bonding layer between the bare metal substrate 102 and any additional layers deposited on top of it. In some examples, this optional layer on the substrate, 103, is 500 Angstroms (Å) thick. In some examples, this optional layer on the substrate 103 is between 10 Å and 1000 Å thick as described herein.

The example diagram of FIG. 1 also shows a carbon layer 104. In some examples, this carbon layer 104 may be a layer of diamond-like carbon (DLC). In some examples, this carbon layer 104 may be nitrogen doped diamond-like carbon (NDLC) as described herein. In some examples, this carbon layer 104 is layered on top of the optional layer on the substrate 103. Alternatively, in some examples, this NDLC layer is applied directly to the blade substrate 102 itself.

In some examples, this carbon layer, such as for example, an NDLC layer, is from undetectable up to 20,000 Å thick. In some examples, this carbon layer is up to 50,000 Å thick as described herein.

As shown in the example of FIG. 1, another optional layer 106 on the carbon layer 104. In some examples, this optional layer on the carbon layer 104 may be a layer of Cr 106 on top of the carbon, DLC, or NDLC layer 104. As mentioned for the optional layer under the carbon directly on the substrate described earlier, this layer on top of the carbon layer is also optional. Additionally or alternatively, this optional layer on top of the carbon layer could be any of, alone or in any combination of silicon (Si), zirconium (Zr), chromium (Cr), niobium (Nb), tungsten (W), boron (B), and/or titanium (Ti). In some examples, this optional layer on top of the carbon is about 500 Å thick. In some examples, this layer is between 10 Å and 1000 Å thick.

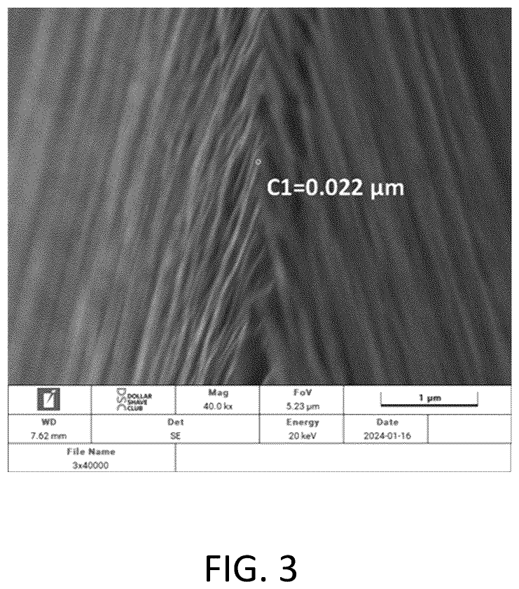

FIG. 3 shows a photo taken at microscopic level of an NDLC coated blade edge. The radius at the tip of this blade edge shown is measured at 0.02 μm.

In some examples, systems and methods given here may be used to both strengthen the blades tips and sharpen them to an improved blade tip radius. In such examples, a biased NDLC coating may be applied that both strengthens and hones the blade edge using nitrogen doping and ion beams, as described herein. FIG. 3 shows a photo taken at microscopic level of an NDLC coated blade edge. The radius of the tip of this blade edge shown is measured at 0.022 μm. A biased NDLC coated blade edge as shown, would both strengthen the blade edge using the added carbon layer and also impart a shave experience that is improved with the honed tip as described herein.

Finally, a last optional layer is shown on top, as an outermost layer 108. In some examples, this last, optional, outermost layer may be made of a polymer or include polymers 108. In some examples, the polymer may be polytetrafluoroethylene (PTFE) or any suitable substitute. This final, optional, outermost layer may be used to reduce the friction coefficient of the blade against the skin and the hair of the user during a shave.

In some examples, any number of layers described herein may be placed on the blade substrate 102. In some examples, multiple layers may be applied. The order of layers or their compositions may be changed depending on the example embodiment. The methods used to deposit the layers mentioned above may vary and embodiments are described below.

### Nitrogen Doped Carbon Coating Layer Examples

In some examples, the layers or coatings may be applied to the blades using a Physical Vapor Deposition (PVD) process, in a vacuum chamber, using a high voltage magnetron sputtering source, as described. Sputtering is a method of physical vapor deposition using atoms from a target material placed in a vacuum chamber with the blades to be coated, which together with ionized gases, form a deposited layer that bombards the blades with atoms from the target and coats the razor blade edges with those target material atoms. The target material to be used as the coating is placed in the vacuum chamber which is first vacuumed and then backfilled with a gas such as Argon (Ar). The target material is thereby deposited as a layer on the subject, in this case the razor blade(s). In some examples here, chromium may be the target which is sputtered onto the blades as described. In some examples here, carbon, graphite, and/or graphene may be the target which is sputtered onto the blades as a carbon layer as described.

Referring back to the carbon layer 104 of FIG. 1, doping carbon, or diamond-like carbon coating layer with nitrogen, boron, fluorine, silicon and/or silver may be used instead of simply using Ar gas. Doping with nitrogen, in the context of sputtering, includes intentionally incorporating nitrogen atoms into the vapor deposition process and thereby incorporating nitrogen into whichever target material is being sputter deposited. Thereby, in some examples, as described, nitrogen (N) is mixed with the Ar used to sputter the carbon to form a nitrogen doped diamond-like carbon (NDLC) layer.

In these cases, where carbon is the target, as the carbon is deposited onto the blades, nitrogen atoms from the gas mixed with Carbon atoms is deposited into the crystal lattice of the deposited material. This process produces a layer of carbon material with altered chemical properties. In some examples, incorporation of nitrogen into the diamond-like carbon results in a most positive result, by lowering the coating internal stresses, while enhancing its mechanical properties to improve the coating by adding strength and durability.

As known to those knowledgeable in the art, Nitrogen doping is different from nitriding which is introducing N into the steel metal substrate in between atoms of the iron. Nitrogen doping the coating instead, deposits the C and the N atoms together and builds an N doped diamond like C layer which is applied on top of the stainless-steel blades and/or on top of an optional layer which is on the stainless-steel blades.

### Sputtering Method Examples

For the sputtering steps described above, a pulsed DC current may be applied to the target coating material and an optional negative bias charge is applied to the razor blades. The DC current may be cycled on and off to ionize the gas in the chamber and ignite a plasma. The atoms of the target material may then be accelerated and moved toward the razor blades. This bombardment results in a thin coating of target material atoms deposited on the razor blades.

The power setting of the sputtering power supply determines the coating rate. In some examples, the Cr Sputter Power in the system is between 500 W-5000 W. A preferred embodiment is between 2,000-4,000 W. In some examples, the Pulse Frequency in the system is between 50 kHz-3000 kHz. A preferred embodiment is between 100 kHz-600 kHz.

The application of an optional reverse pulse in magnetron sputter coating allows for greater control over the deposition process, leading to improvements in film quality, adhesion, microstructure, and other relevant properties. In some examples, systems and methods here use an optional reverse pulse time between 0 μs-100 μs. A preferred embodiment is between 1-5 μs.

In some examples, the optional negative bias level is between 0 kV-2 kV. A preferred embodiment is between 0.5 kV-1.5 kV.

In some examples, the voltage bias may be between 0 kV-30 kV. In some examples, the voltage bias is between 0.5 kV-3 kV.

The power setting of the sputtering power supply determines the coating rate. In some examples, the C sputter power in the system is between 500 W-5,000 W. A preferred embodiment is between 2,000 W-4,000 W.

In some examples, the method of applying the target coating has a coating timing of between 25 seconds-2,500 seconds. A preferred embodiment is between 50 seconds-250 seconds.

In these examples, process variables and values are given as examples only, but these are not limiting the even wider possibilities in order to achieve the desired result. Any combination or permutation of any of the variables above may be used to apply the layers to the razor blades as described.

### Honing and Shaping Using Bias Examples

As described, to improve the NDLC layering, Ar and NDLC may be used to hone and/or sharpen the blade tip. Such a method may utilize directional control of Ar ion bombardment on the tip that can be used to sharpen the tip at a microscopic level. In some examples, the nitrogen doped carbon gas may even deposit an extra sharp carbon layer on the layer below it to enhance the sharpness of the blade. Such a method may result in a sharper tip due to the ion beam directional bombardment coupled with the strengthened and deposited carbon tip using the NDLC sputtering. In some examples, additionally or alternatively, the bombardment of Ar and NDLC may even hone the blade surfaces to further sharpen the blades while simultaneously depositing the Carbon layer as described herein. Such a process may be achieved in the vacuum chamber as described.

### Method or Process Step Examples

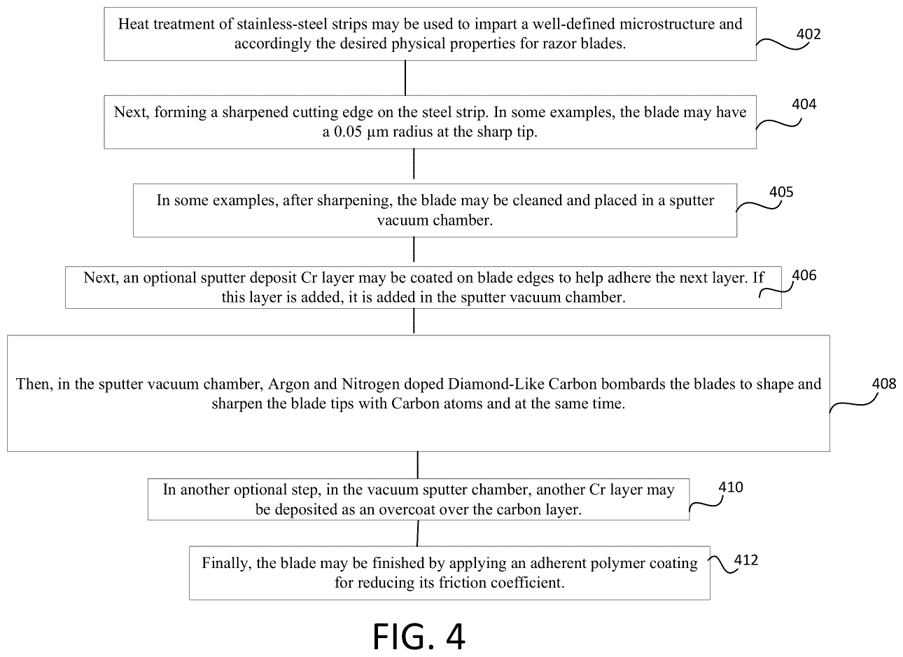

FIG. 4 shows an example flow chart of process steps for manufacturing a razor blade using the systems and methods as described here. As shown in FIG. 4:

To achieve the results described here, methods may be practiced to treat bare metal blade substrates and apply the coating layers. In an example method, the razor blade production begins with 402 heat treatment of stainless-steel strips to impart a well-defined microstructure and accordingly the desired physical properties for razor blades.

The edge may then be sharpened mechanically, by grinding, to achieve a specific geometry. In such examples, the blade shape may be a gothic arch shape 404. Forming a sharpened cutting edge on the steel strip may result in a 0.05±0.04 μm radius at the sharp tip as shown in FIG. 2.

In some examples, 405 after sharpening, the blade may be cleaned and placed in a sputter vacuum chamber.

In some examples, as described herein, the sputter target is a Chromium sputter target, and results in a sputtering coat of an optional layer of Cr, 406 on blade edges to help adhere the next layer. As described, this optional Cr interlayer on the steel is preferentially between 10 Å and 1000 Å thick.

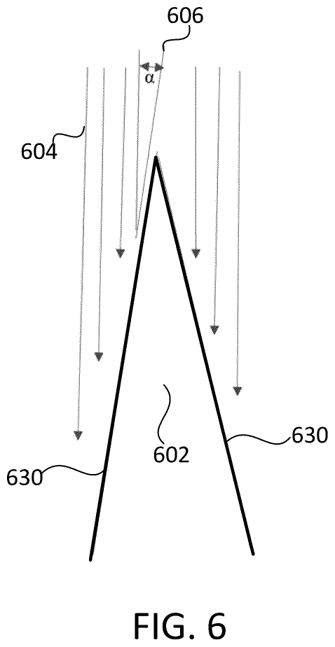

Then, in the sputter vacuum chamber, Argon and Nitrogen doped Diamond-Like Carbon bombards the blades to shape and sharpen the blade tips with Carbon atoms and at the same time, the Argon ion bombardment also removes some of the sides of the blade edges, 408. Further detail is shown in FIG. 6.

Next, Argon (Ar) is introduced into the chamber and a carbon (C) layer is sputtered from a graphite target. In some examples, nitrogen (N) is added to this Argon and an NDLC layer is achieved. The use of Nitrogen results in a most positive result, by lowering the coating internal stresses, while enhancing its mechanical properties. The diamond-like carbon coating layer adhesion to the steel substrate and toughness is improved by the incorporation of a given number of Nitrogen atoms than just using Carbon atoms.

In some examples, the Nitrogen concentration in the sputtering vacuum chamber may be between 1-70 vol %. A preferred embodiment is between 5-25 vol %. The diamond-like carbon deposition combines with the Nitrogen to form the NDLC layer. In some examples, the diamond-like carbon (C) layer is from a graphite target and in some examples, the diamond-like carbon is from carbon containing gases. In either case, the Carbon layer includes some of the Nitrogen from the Nitrogen gas added to the chamber. In some examples, this NDLC layer is up to 50,000 Å thick. The resulting Nitrogen concentration in the deposited NDLC layer may be up to 75 wt %. A preferred embodiment is between 20-65 wt %.

In another optional step, 410 in the vacuum sputter chamber, another layer may be deposited as an overcoat over the carbon layer. In some examples this is another Cr layer. As described, the layer(s) could be substituted for any number of other materials. Other examples of material may include in any combination or permutation, silicon (Si), zirconium (Zr), chromium (Cr), niobium (Nb), tungsten (W), boron (B), and/or titanium (Ti), may be used.

Finally, 412 the blade may be finished by applying an adherent polymer coating for reducing its friction coefficient. This may be finished with a final top layer of PTFE or other substitute polymer layer for friction reduction, as described. In some examples, the polymer layer is sprayed on and then heated to cure it. It can also be sputtered on like the Cr or NDLC layers.

### NDLC Deposit Examples

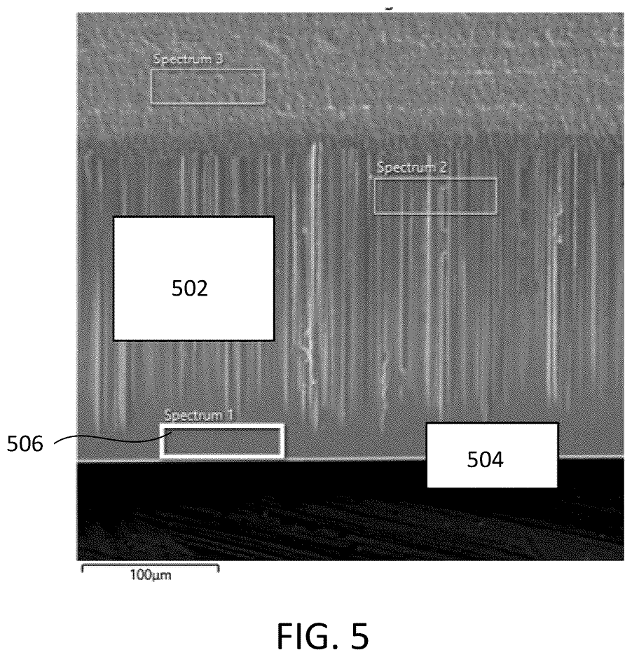

As shown in FIG. 5 showing a photo of an electron microscopic enlargement of an edge of a blade made using the systems and methods described herein. The example blade is made using described methods for sharpening the grinding zone 502 and the tip edge 504 of a blade using NDLC physical vapor deposition.

Using the methods described herein, a blade edge may be generated which has a carbon and nitrogen composition of NDLC coating which provides a stronger blade as described herein. Below is a table showing such examples of how much C and N by weight percentage may be found in the resulting tip coating using the systems and methods described herein where Weight % is the relative concentration of the element in weight percent in the NDLC coating, and Weight % Sigma is the error of the measured values:

TABLE 1

| Spectrum at Tip Edge 504 | | |
|---|---|---|
| Element | Weight % | Weight % Sigma |
| C | 55.83 | 1.41 |
| N | 44.17 | 1.41 |

Below is a table showing more examples ranges of how much C and N by weight percentage may be found in a resulting tip coating, using the systems and methods described herein:

TABLE 2

| Spectrum at Tip Edge 504 | |
|---|---|
| Element | Weight % |
| C | 52-56 |
| N | 42-46 |

FIG. 6 shows application of NDLC using the same sputtering method but this time with an added feature of applying a voltage bias to the blade tip 602. The result is that the charged particles of Ar 604 in the physical deposition chamber are attracted toward the blade tip and accelerate toward it in generally the same direction 604 to bombard the tip 602. In such examples, a higher opposite polarity between the tip and the source target creates this environment of accelerating particles. In such examples, when the voltage bias is applied, the Argon ions hit the blade tip 606 and shear off, collide with and knock off particles of C and N already deposited on the blade 602. Such a method results in a honing of the blade tip 602 into a sharper edge with the accelerated bombardment of Argon ions 604. In some examples, additionally or alternatively, other gasses or materials may be used in the physical vapor deposition process.

In such examples, the sputtering magnetron sources and targets are set up such that the directional beam of ions 604 hits the razor blade tips 602 at an angle α of less than 25 degrees 606. In some examples, the angle α 606 may be between 10 and 30 degrees. In some preferred examples, the angle α 606 may be between 10 and 20 degrees. In some examples, the angle is the physical angle of the tip itself which is between 13-14 degrees.

The simultaneous deposition of C layer and Ar etching effects are shown in FIG. 6. In FIG. 6, the diagram demonstrates the bombardment of Ar ions on the blade 602. In some examples, this blade 602 includes the underlying stainless-steel but also some NDLC 604 which was deposited on the blade 602. This dual-action depositing of NDLC with Ar ions results in shearing of blade flanks and depositing carbon on the blade and tip.

As can be seen, the angle α 606 of the bombardment of the Ar and NDLC particles 604 may have an effect on the deposition of the C on the blade. Additionally, factors such as the bias, timing, and amounts of materials described herein may affect the deposition of the C on the blade. In some examples, alpha is less than 25 degrees from vertical.

This method can turn a blade as shown in FIG. 2 with a larger, 0.2 μm radius tip into one as shown in FIG. 3 with an NDLC layer buildup of a desired geometry and tip sharpness where the tip radius of the directionally controlled ion beam process is reduced to about 0.022 μm.

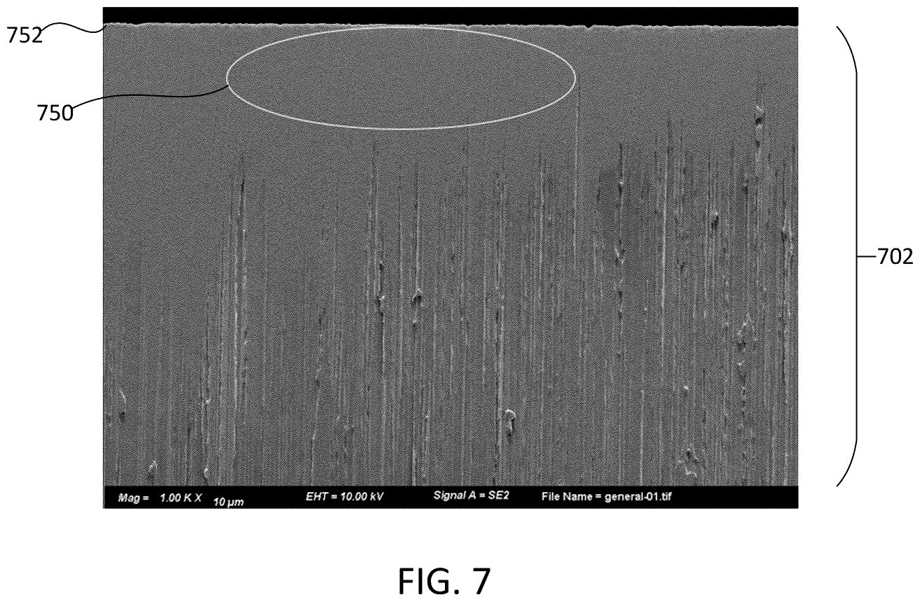

FIG. 7 shows an image taken using an electron microscope at 1000× magnification of a blade edge having been treated as described herein. As can be seen in the image, the blade 702 includes a tip edge 752 and below that a layer of C 750. These show the effects of the particle bombardment on the edges and the C layer, using the systems and methods described here.

The outcome of these systems and method steps is that the blade gets sharpened to an almost atomic level, achieving a superior sharpening with a small diameter tip while also gaining the carbon layer strength. In some examples, the approximate resulting tip diameter may be around 22 nm. In some examples, the approximate tip diameter may be between 20 nm and 24 nm. In some examples, the approximate tip diameter may be between 18 nm and 26 nm.

In these examples, this bias etch sharpening may be aided by a combination with a certain concomitant coating flux of Carbon atom deposits. Thus, this method both deposits carbon and etches the blade with Ar ions at the same time. In some examples, this bias etch sharpening may be aided by a combination with a certain concomitant coating flux of other materials, such as but not limited to: silicon (Si), zirconium (Zr), chromium (Cr), niobium (Nb), tungsten (W), boron (B), and/or titanium (Ti), or similar. In some examples, this bias etch sharpening may be aided by a combination with a certain concomitant coating flux of a combination of any of the above materials.

### CONCLUSION

The foregoing description, for the purpose of explanation, has been described with reference to specific embodiments. However, the illustrative discussions above are not intended to be exhaustive or to limit the embodiments to the precise forms disclosed. Many modifications and variations are possible in view of the above teachings. The embodiments were chosen and described to best explain the principles of the embodiments and their practical applications, to thereby enable others skilled in the art to best utilize the various embodiments with various modifications as are suited to the particular use contemplated.

Unless the context clearly requires otherwise, throughout the description, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

Although certain presently preferred implementations of the embodiments have been specifically described herein, it will be apparent to those skilled in the art to which the embodiments pertain that variations and modifications of the various implementations shown and described herein may be made without departing from the spirit and scope of the embodiments. Accordingly, it is intended that the embodiments be limited only to the extent required by the applicable rules of law.

What is claimed is:

1. A method for manufacturing a shaving razor blade, the method comprising:
providing a heat-treated stainless-steel strip;
grinding a sharpened cutting edge with a cutting edge tip on the stainless-steel strip; and
using a physical vapor deposition system for applying a bias voltage to the stainless-steel strip and depositing a Nitrogen-containing Diamond Like Carbon (NDLC) coating by directional ion beams of Argon, Nitrogen, and Carbon and thereby coating the blade cutting edge tip and also sharpening the blade cutting edge tip.

2. The method of claim 1 wherein the sharpening of the blade tip has a radius of about 0.02 μm.

3. The method of claim 1 wherein the physical vapor deposition system bias voltage level is between 0 kV and 30 kV.

4. The method of claim 1 further comprising, depositing a first Cr coating on the cutting edge using a physical vapor deposition system, before the NDLC coating.

5. The method of claim 1 further comprising, depositing an NDLC coating on the cutting edge using a physical vapor deposition system.

6. The method of claim 1 further comprising, depositing a second Cr coating on the NDLC layer using the physical vapor deposition system.

7. The method of claim 1 further comprising, applying an adherent polymer coating for reducing friction coefficient.

8. The method of claim 1 wherein the NDLC is deposited by a magnetron sputter coating source.

9. The method of claim 1 wherein the NDLC is deposited in an evacuated chamber in which a graphite target is used.

10. The method of claim 1 wherein the NDLC is deposited in an evacuated chamber in which a composite carbon target with any one or any combination of silicon (Si), zirconium (Zr), chromium (Cr), niobium (Nb), tungsten (W), boron (B), and/or titanium (Ti).

11. The method of claim 10 wherein the evacuated chamber atmosphere includes any combination of Argon, Nitrogen, Fluorine-containing, and/or Carbon-containing gas, at low pressure.

12. The method of claim 1 wherein the directional ion beams of Argon, Nitrogen, and Carbon directional beam of ions is at an angle of less than 25 degrees relative to the blade edge tip.

13. The method of claim 1 wherein the physical vapor deposition system includes a high energy source having an energy of at least 10 volts.

14. The method of claim 1 further comprising multiple stainless-steel strips combined into stacks and wherein Sputter Power for the powered physical vapor deposition system used for each blade stack is between 500 W and 5000 W.

15. The method of claim 1 wherein the physical vapor deposition system uses a power supply that is a pulsed DC with a Pulse Frequency of between 50 kHz and 30,000 kHz.

16. The method of claim 1 wherein the physical vapor deposition system has a Reversed Pulse Time of between 0 μs-100 μs.

17. The method of claim 1 wherein the physical vapor deposition system includes Nitrogen gas concentration between 0 vol % and 70 vol %.

18. The method of claim 1 wherein, bias voltage is between 0.5 kV-3 kV.

19. The method of claim 1 wherein a time to apply all the layers to the blades is between 25 seconds and 25,000 seconds.

20. The method of claim 1 wherein the NDLC coating results in a blade cutting edge coating having between 53% and 93% weight C.

21. The method of claim 1 wherein the NDLC coating results in a blade cutting edge coating having between 7% weight N and 47% weight N.

22. A razor blade, comprising:
a stainless-steel strip having a sharpened cutting edge,
the stainless-steel strip cutting edge including a nitrogen-containing diamond-like carbon (NDLC) coat on the stainless-steel cutting edge and tip, from the physical vapor deposition system, wherein the NDLC coating is from directional voltage biased ion beams of Argon, Nitrogen, and Carbon in the physical vapor deposition system, and wherein the NDLC coating results in a blade having between 53-93% weight C and 7-47% weight N.

23. The razor blade of claim 22 wherein a first Cr coating from a physical vapor deposition system, before the NDLC coating.

24. The razor blade of claim 22 wherein a second Cr coating on the cutting edge on top of the NDLC coating from the physical vapor deposition system.

25. The razor blade of claim 22 wherein the tip is honed using a directional ion beam shaping with a bias between the stainless-steel strip and a carbon target and a cutting edge tip radius of about 0.02 μm after the NDLC coating using directional voltage biased ion beams.

26. The razor blade of claim 22 wherein the voltage bias is between 0 kV and 30 kV.

27. The razor blade of claim 22 wherein the physical vapor deposition system includes Nitrogen gas concentration between 0 vol % and 70 vol %.
